(19) United States
(12) Patent Application Publication
(10) Pub. No.: US 2018/0195690 A1
(43) Pub. Date: Jul. 12, 2018

(54) WAVELENGTH CONVERSION MEMBER AND LIGHT-EMITTING DEVICE

(71) Applicant: Sharp Kabushiki Kaisha, Sakai City (JP)

(72) Inventors: Tatsuya Ryohwa, Sakai City (JP); Noriyuki Yamazumi, Sakai City (JP); Kenichi Yoshimura, Sakai City (JP); Hiroshi Fukunaga, Sakai City (JP); Kanako Nakata, Sakai City (JP); Makoto Izumi, Sakai City (JP)

(21) Appl. No.: 15/834,215

(22) Filed: Dec. 7, 2017

(30) Foreign Application Priority Data
Jan. 11, 2017 (JP) 2017-002474

(51) Int. Cl. F21V 9/30; H01L 33/50; C09K 11/64; C09K 11/02; C09K 11/88

(52) U.S. Cl. CPC F21V 9/30; H01L 33/501; C09K 11/646; H01L 33/504; C09K 11/883; H01L 33/502; C09K 11/025

(57) ABSTRACT

A wavelength conversion member includes a light-transmitting medium and phosphor-containing particles dispersed in the light-transmitting medium and including a resin and a semiconductor nanoparticle phosphor dispersed in the resin, wherein the phosphor-containing particles have a particle size that is equal to or larger than a particle size of the semiconductor nanoparticle phosphor and that is equal to or smaller than a minimum thickness of the wavelength conversion member. A light-emitting device includes a light source and a wavelength converter including a light-transmitting medium and phosphor-containing particles including a resin including a constitutional unit derived from an ionic liquid having a polymerizable functional group and a semiconductor nanoparticle phosphor dispersed in the resin, wherein the phosphor-containing particles have a particle size that is equal to or larger than a particle size of the semiconductor nanoparticle phosphor and that is equal to or smaller than a minimum thickness of the wavelength converter.

### BACKGROUND

### 1. Field

The present disclosure relates to a wavelength conversion member and a light-emitting device.

### 2. Description of the Related Art

Semiconductor nanoparticle phosphors (also referred to as quantum dots), which have an electron characteristic that is size-tuneable due to the quantum size effect, have been attracting commercial interest. The size-tuneable electron characteristic is applicable to a variety of applications such as biological labeling, photovoltaic power generation, catalysis, biological image pick-up, LEDs, general space lighting, and electron emission displays.

However, when semiconductor nanoparticle phosphors are directly added to encapsulation materials such as silicone and acrylate, the following problems may occur. The nanoparticles agglomerate to form agglomeration, which causes degradation of the optical characteristics. After the nanoparticles are encapsulated, oxygen permeates the encapsulation material to the surfaces of the nanoparticles and causes photooxidation, which results in a decrease in the quantum yield. In addition, because the semiconductor nanoparticle phosphors cause resorption and the like, color control is very difficult to achieve.

In order to address such problems, for example, Japanese Unexamined Patent Application Publication (Translation of PCT Application) No. 2012-509604 proposes a formulation including a population of semiconductor nanoparticles incorporated into a plurality of discrete microbeads comprised of an optically transparent medium, the nanoparticle-containing medium being embedded in a host light-emitting diode (LED) encapsulation medium.

However, in the method disclosed in Japanese Unexamined Patent Application Publication (Translation of PCT Application) No. 2012-509604, microbeads have excessively small or large particle sizes of about 20 nm to 0.5 mm, which results in sedimentation, agglomeration, or the like during embedding into an LED encapsulation medium. Thus, uniform dispersion of the microbeads is difficult to achieve. When the microbeads are used in an on-chip configuration or used as a wavelength conversion member, since the microbeads cannot be uniformly dispersed, color control is difficult to achieve. In addition, a reduction in the size and a reduction in the thickness are difficult to achieve.

### SUMMARY

It is desirable to provide a wavelength conversion member and a light-emitting device in which phosphor-containing particles containing a semiconductor nanoparticle phosphor are uniformly dispersed and that enable a reduction in the size and a reduction in the thickness.

According to an aspect of the disclosure, there is provided a wavelength conversion member including a light-transmitting medium and phosphor-containing particles dispersed in the light-transmitting medium and including a resin including a constitutional unit derived from an ionic liquid having a polymerizable functional group and a semiconductor nanoparticle phosphor dispersed in the resin, wherein the phosphor-containing particles have a particle size that is equal to or larger than a particle size of the semiconductor nanoparticle phosphor and that is equal to or smaller than a minimum thickness of the wavelength conversion member.

According to another aspect of the disclosure, there is provided a light-emitting device including a light source and a wavelength converter joined to the light source so as to cover at least a portion of the light source and including a light-transmitting medium, and phosphor-containing particles dispersed in the light-transmitting medium and including a resin including a constitutional unit derived from an ionic liquid having a polymerizable functional group, and a semiconductor nanoparticle phosphor dispersed in the resin, wherein the phosphor-containing particles have a particle size that is equal to or larger than a particle size of the semiconductor nanoparticle phosphor and that is equal to or smaller than a minimum thickness of the wavelength converter.

### BRIEF DESCRIPTION OF THE DRAWINGS

FIG. 1A is a sectional view schematically illustrating a phosphor-containing particle used in a wavelength conversion member and a light-emitting device according to embodiments;

FIG. 1B is a schematic view illustrating a wavelength conversion member according to an embodiment;

FIGS. 2A to 2G are schematic views illustrating the minimum thicknesses of wavelength conversion members;

FIGS. 3A to 3C are explanatory views illustrating the relationship between the particle size of phosphor-containing particles and the minimum thickness of a wavelength conversion member;

FIG. 4 is a schematic view illustrating a phosphor-containing particle having a particle size in a range of 1 to 30 μm;

FIG. 5 is a schematic view illustrating a phosphor-containing particle according to another embodiment;

FIG. 6 is a schematic view illustrating a wavelength conversion member according to another embodiment;

FIG. 7 is a schematic view illustrating a light-emitting device according to another embodiment; and

FIG. 8 is a schematic view illustrating a light-emitting device according to another embodiment.

### DESCRIPTION OF THE EMBODIMENTS

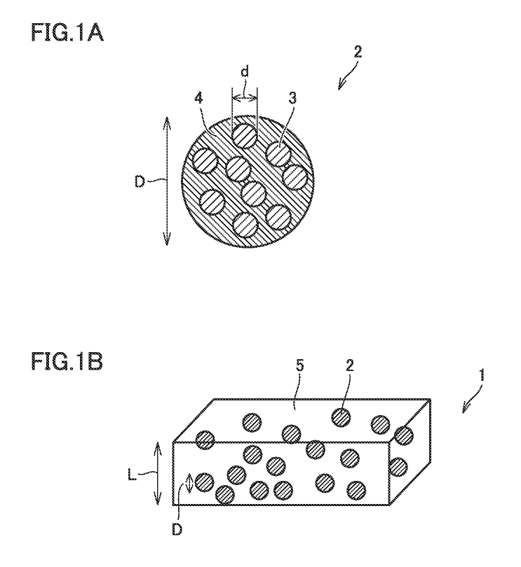

FIG. 1A is a sectional view schematically illustrating a phosphor-containing particle 2 used in a wavelength conversion member and a light-emitting device according to embodiments. FIG. 1B is a schematic view illustrating a wavelength conversion member 1 according to an embodiment. The phosphor-containing particle 2 according to an embodiment includes a semiconductor nanoparticle phosphor 3, and a resin 4 including a constitutional unit derived from an ionic liquid having a polymerizable functional group, wherein the semiconductor nanoparticle phosphor 3 is dispersed in the resin 4. The wavelength conversion member 1 according to an embodiment has a feature that the phosphor-containing particles 2 have a particle size D that is equal to or larger than a particle size d of the semiconductor nanoparticle phosphor 3, and that is equal to or smaller than a minimum thickness L of the wavelength conversion member.

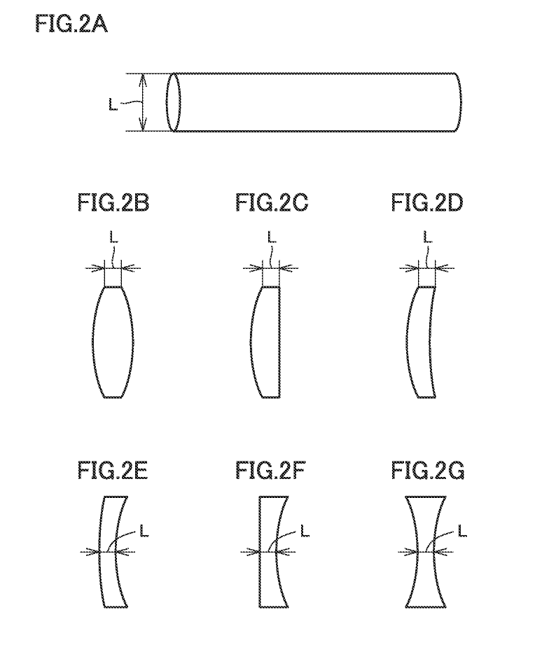

The minimum thickness L of each of wavelength conversion members having different shapes within the scope of the present disclosure denotes, in a portion having the minimum linear distance in the wavelength conversion member, this linear distance. Specifically, for example, as illustrated in FIG. 1B, when the wavelength conversion member 1 substantially has a rectangular parallelepiped shape, the length (linear distance) of the shortest side among the sides of the wavelength conversion member 1 serves as the minimum thickness L. Alternatively, when the wavelength conversion member has a sheet shape, the linear distance in the thickness direction normally serves as the minimum thickness L. Alternatively, as illustrated in FIG. 2A, when the wavelength conversion member has a cylindrical shape and a linear distance in a direction perpendicular to a circular section is larger than the diameter of the section, the diameter serves as the minimum thickness L. On the other hand, when the wavelength conversion member has a cylindrical shape but the diameter of a circular section is larger than a linear distance in a direction perpendicular to the section (the wavelength conversion member may have a disc shape), the linear distance in the direction perpendicular to the circular section serves as the minimum thickness L.

Hereinafter, the minimum thickness will be described with reference to specific examples illustrated in FIGS. 2B to 2G. FIGS. 2B to 2G illustrate cases where the section illustrated in FIG. 2A is replaced by the sections illustrated in FIGS. 2B to 2G, and a linear distance in a direction perpendicular to such a section is not the minimum distance. FIG. 2B illustrates a section having a shape including two opposite sides and curved surfaces that are convex in opposite directions. In this case, the length (linear distance) of the two opposite sides serves as the minimum thickness L. FIG. 2C illustrates a section having a shape including two opposite sides, one side perpendicular to these two sides, and a curved surface convex in a direction away from the one side. In this case, the length (linear distance) of the two opposite sides serves as the minimum thickness L. FIG. 2D illustrates a section having a shape that includes two opposite sides, one side convex outwardly, and one side concave inwardly, and that has the maximum thickness substantially in the middle portion between the two opposite sides; in other words, the section has, what is called, a convex meniscus shape. In this case, the length (linear distance) of the two opposite sides serves as the minimum thickness L. FIG. 2E illustrates a section having a shape that includes two opposite sides, one side convex outwardly, and one side concave inwardly, and that has the minimum thickness substantially in the middle portion between the two opposite sides; in other words, the section has, what is called, a concave meniscus shape. In this case, the minimum linear distance substantially in the middle portion between the two opposite sides serves as the minimum thickness L. FIG. 2F illustrates a section having a shape including two opposite sides, one side perpendicular to these two sides, and a curved surface concave toward the one side. In this case, the minimum linear distance substantially in the middle portion between the two opposite sides serves as the minimum thickness L. FIG. 2G illustrates a section having a shape including two opposite sides and curved surfaces concave toward each other. In this case, the minimum linear distance substantially in the middle portion between the two opposite sides serves as the minimum thickness L.

In the present disclosure, the particle size D of the phosphor-containing particles 2, the particle size d of the semiconductor nanoparticle phosphor 3, and the minimum thickness L of the wavelength conversion member satisfy the following relationship:

d≤D≤L.

When the particle size D of the phosphor-containing particles 2 is less than the particle size d of the semiconductor nanoparticle phosphor 3 (that is, D<d), the surface of the semiconductor nanoparticle phosphor 3 may not be sufficiently protected with the resin 4. When the particle size D of the phosphor-containing particles 2 is more than the minimum thickness L of the wavelength conversion member 1 (that is, D>L), the phosphor-containing particles 2 may be deformed and damaged, so that protection of the semiconductor nanoparticle phosphor 3 due to the phosphor-containing particles is not achieved. In addition, deformation is caused from the designed shape of the wavelength conversion member. In the present disclosure, the particle size D of the phosphor-containing particles 2 is equal to or larger than the particle size d of the semiconductor nanoparticle phosphor 3, and equal to or smaller than the minimum thickness L of the wavelength conversion member. As a result, while the semiconductor nanoparticle phosphor is protected with the resin including a constitutional unit derived from an ionic liquid, the phosphor-containing particles 2 are dispersed, without being deformed or damaged, in a medium 5.

In the present disclosure, the particle size D of the phosphor-containing particles 2 may be equal to or larger than twice (2×d) the particle size d of the semiconductor nanoparticle phosphor 3, and may be equal to or smaller than ½ (½×L) of the minimum thickness L of the wavelength conversion member 1. That is, the particle size D of the phosphor-containing particles 2, the particle size d of the semiconductor nanoparticle phosphor 3, and the minimum thickness L of the wavelength conversion member may satisfy the following relationship:

2×d≤D≤½×L.

When the particle size D of the phosphor-containing particles 2 is equal to or larger than twice (2×d) the particle size d of the semiconductor nanoparticle phosphor 3, each phosphor-containing particle 2 is able to protect at least two particles of the semiconductor nanoparticle phosphor 3. When the particle size D of the phosphor-containing particles 2 is equal to or smaller than ½ (½×L) of the minimum thickness L of the wavelength conversion member 1, at least two phosphor-containing particles 2 are dispersed, without being deformed or damaged, in the medium 5.

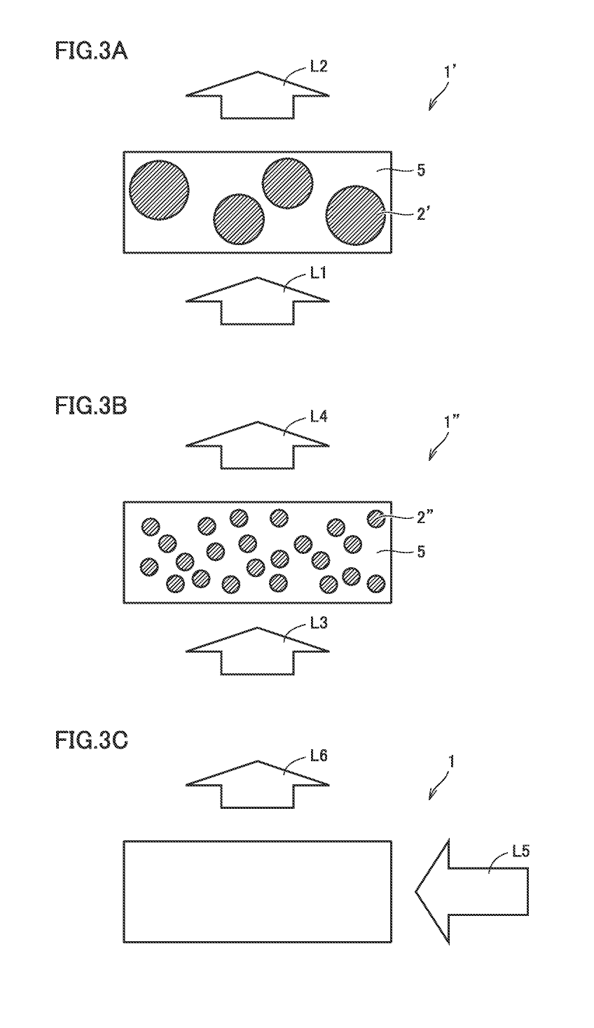

FIGS. 3A to 3C illustrate the relationship between the particle size of phosphor-containing particles and the minimum thickness of a wavelength conversion member. For example, FIG. 3A illustrates a case in which the particle size D of phosphor-containing particles 2′ is larger than ½ of the minimum thickness L of a wavelength conversion member 1′ and is smaller than the minimum thickness L (½×L<D<L). In the case illustrated in FIG. 3A, in which the phosphor-containing particles 2′ within the wavelength conversion member 1′ have a relatively large particle size, the wavelength conversion member 1′ may be clearly divided into a region including the semiconductor nanoparticle phosphor and a region not including the semiconductor nanoparticle phosphor, in other words, the semiconductor nanoparticle phosphor may be unevenly dispersed. As a result, when excitation light (primary light) L1 is made to enter the wavelength conversion member 1′, variations may be caused in emission of fluorescence (secondary light) L2 provided from the semiconductor nanoparticle phosphor contained in the phosphor-containing particles 2′, the emission being caused by the excitation light L1. By contrast, for example, in the case illustrated in FIG. 3B, in which the particle size D of phosphor-containing particles 2″ is equal to or smaller than ½ of the minimum thickness L of a wavelength conversion member 1″ (D≤½×L), the wavelength conversion member 1″ does not have the clear division into a region including the semiconductor nanoparticle phosphor and a region not including the semiconductor nanoparticle phosphor, and the semiconductor nanoparticle phosphor is evenly dispersed. As a result, when excitation light (primary light) L3 is made to enter the wavelength conversion member 1″, uniform emission of fluorescence (secondary light) L4 is provided from the semiconductor nanoparticle phosphor contained in the phosphor-containing particles 2″, the emission being caused by the excitation light L3. The absence of such variations in emission facilitates color (concentration) control. Thus, in the present disclosure, the upper limit of the particle size D of the phosphor-containing particles is equal to or smaller than the minimum thickness L of the wavelength conversion member (D≤L), and is preferably equal to or smaller than ½ of the minimum thickness L of the wavelength conversion member (D≤½×L). Such variations in emission are also caused in, as illustrated in FIG. 3C, a case where the direction of entry of excitation light (primary light) L5 intersects the emission direction of fluorescence (secondary light) L6. Also in this case, from the viewpoint of achieving uniform emission, the upper limit of the particle size D of the phosphor-containing particles is preferably equal to or smaller than ½ of the minimum thickness L of the wavelength conversion member (D≤½×L).

In the present disclosure, when the upper limit of the particle size D of the phosphor-containing particles is equal to or smaller than ½ of the minimum thickness L of the wavelength conversion member (D≤½×L), the phosphor-containing particles are dispersed in the light-transmitting medium without causing, for example, clogging of the dispenser or sedimentation. Thus, by mounting the phosphor on, for example, an LED device by the same production process as in the existing phosphors, a light-emitting device according to an embodiment is produced.

The wavelength conversion member 1 according to an embodiment in FIG. 1B may be equipped with a light source (excitation light source) that is disposed as another member in addition to the wavelength conversion member 1, to thereby provide a light-emitting device according to an embodiment. The term “another member” means that the wavelength conversion member 1 and the light source are different members and are not formed as one piece.

The “ionic liquid” used for the present disclosure is a salt in a molten state even at an ordinary temperature (for example, 25° C.) (molten salt at ordinary temperature), and may be represented by the following general formula (I):

X⁺Y⁻ (I).

In the general formula (I), X⁺ represents a cation selected from an imidazolium ion, a pyridinium ion, a phosphonium ion, aliphatic quaternary ammonium ions, a pyrrolidinium ion, and a sulfonium ion. Of these, the cation may be selected from aliphatic quaternary ammonium ions because of the high stability against air and moisture in the atmosphere.

In the general formula (I), Y⁻ represents an anion selected from a tetrafluoroborate ion, a hexafluorophosphate ion, a bistrifluoromethylsulfonylimidate ion, a perchlorate ion, a tris(trifluoromethylsulfonyl)carbonate ion, a trifluoromethanesulfonate ion, a trifluoroacetate ion, a carboxylate ion, and halogen ions. Of these, the anion may be a bistrifluoromethylsulfonylimidate ion because of the high stability against air and moisture in the atmosphere.

The ionic liquid used for the present disclosure has a polymerizable functional group. The ionic liquid having a polymerizable functional group is used, so that the ionic liquid functioning as a dispersion liquid of the semiconductor nanoparticle phosphor is itself polymerized with the polymerizable functional group. In this way, the ionic liquid having a polymerizable functional group in which the semiconductor nanoparticle phosphor is dispersed is polymerized to form a resin including a constitutional unit derived from the ionic liquid having the polymerizable functional group. This enables significant reduction or prevention of, for example, agglomeration occurring during solidification of a resin in which a semiconductor nanoparticle phosphor is dispersed. As described above, the semiconductor nanoparticle phosphor is dispersed in the resin including a constitutional unit derived from an ionic liquid having a polymerizable functional group, so that the semiconductor nanoparticle phosphor is electrostatically stabilized, and the semiconductor nanoparticle phosphor is strongly protected. As a result, the surface of the semiconductor nanoparticle phosphor is protected from air and moisture, to thereby achieve a light-emitting device having a high emission efficiency.

The polymerizable functional group of the ionic liquid is not particularly limited and may be a (meth)acrylate group ((meth)acryloyloxy group) because polymerization is achieved by heating or a catalytic reaction, and the liquid in which the semiconductor nanoparticle phosphor is stably dispersed is itself solidified with the dispersion state being maintained.

Examples of the ionic liquid having a (meth)acrylate group include ionic liquids having high stability against air and moisture in the atmosphere: 2-(methacryloyloxy)-ethyltrimethylammonium bis(trifluoromethanesulfonyl)imide represented by the following formula

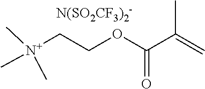

and 1-(3-acryloyloxy-propyl)-3-methylimidazolium bis(trifluoromethanesulfonyl)imide represented by the following formula.

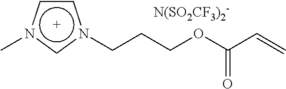

Such ionic liquids having a polymerizable functional group are obtained by introducing, by an appropriately selected known method, a polymerizable functional group into an appropriately selected known ionic liquid. Alternatively, commercially available ionic liquids may be obviously used.

The polymerization conditions such as temperature and time are not particularly limited for the polymerization of an ionic liquid having a polymerizable functional group in which a semiconductor nanoparticle phosphor is dispersed, and the conditions are appropriately selected in accordance with, for example, the type and amount of the selected ionic liquid having a polymerizable functional group. For example, when 2-(methacryloyloxy)-ethyltrimethylammonium bis(trifluoromethanesulfonyl)imide is used as the ionic liquid having a polymerizable functional group, the ionic liquid can be polymerized, for example, at a temperature of 60° C. to 100° C. for 1 to 10 hours. Alternatively, for example, when 1-(3-acryloyloxy-propyl)-3-methylimidazolium bis(trifluoromethanesulfonyl)imide is used as the ionic liquid having a polymerizable functional group, the ionic liquid is polymerized, for example, at a temperature of 60° C. to 150° C. for 1 to 10 hours.

When such polymerization is performed with a catalyst, the catalyst is not particularly limited and examples of the catalyst include known catalysts such as azobisisobutyronitrile and dimethyl 2,2′-azobis(2-methylpropionate). Of these, the catalyst may be azobisisobutyronitrile because polymerization proceeds rapidly.

The semiconductor nanoparticle phosphor 3 according to an embodiment is a single particle phosphor that does not cause scattering of visible light, and is appropriately selected from known semiconductor nanoparticle phosphors without particular limitation. Use of such a semiconductor nanoparticle phosphor enables precise control of the emission wavelength by controlling the particle size and controlling the composition.

The raw material of the semiconductor nanoparticle phosphor is not particularly limited and may be at least one selected from known semiconductor nanoparticle phosphors such as CdS, CdSe, CdTe, ZnS, ZnSe, ZnTe, InN, InP, InAs, InSb, AlP, AlS, AlAs, AlSb, GaN, GaP, GaAs, GaSb, PbS, PbSe, Si, Ge, MgS, MgSe, and MgTe. The semiconductor nanoparticle phosphor may have one of configurations known to those skilled in the art, such as the two-component core configuration, the three-component core configuration, the four-component core configuration, the core-shell configuration, the core-multishell configuration, the doped semiconductor nanoparticle phosphor, and the gradient semiconductor nanoparticle phosphor. FIG. 1A illustrates a case in which a plurality of particles of a single semiconductor nanoparticle phosphor are dispersed in a resin including a constitutional unit derived from an ionic liquid having a polymerizable functional group.

The semiconductor nanoparticle phosphor is not particularly limited in terms of shape and is appropriately selected from, without particular limitation, semiconductor nanoparticle phosphors having known shapes such as a spherical shape, a rod shape, and a wire shape. In particular, from the viewpoint of ease of control of emission characteristics by controlling the shape, a spherical semiconductor nanoparticle phosphor may be used.

The particle size d of the semiconductor nanoparticle phosphor is appropriately selected in accordance with the raw material and the desired emission wavelength and is not particularly limited. However, the particle size d is preferably in a range of 1 to 20 nm, more preferably in a range of 2 to 5 nm. This is because, when the semiconductor nanoparticle phosphor has a particle size d of less than 1 nm, the ratio of surface area to volume is increased, so that surface defects become predominant and the effect tends to be weaker; on the other hand, when the particle size d of the semiconductor nanoparticle phosphor is more than 20 nm, dispersibility is degraded, and agglomeration and sedimentation tend to occur. Incidentally, when the semiconductor nanoparticle phosphor has a spherical shape, the particle size denotes, for example, the average particle size measured with a particle size distribution analyzer or the particle size determined by observation with an electron microscope. Alternatively, when the semiconductor nanoparticle phosphor has a rod shape, the particle size denotes, for example, the lengths of the short axis and the long axis measured with an electron microscope. Alternatively, when the semiconductor nanoparticle phosphor has a wire shape, the particle size denotes, for example, the lengths of the short axis and the long axis measured with an electron microscope.

The amount of semiconductor nanoparticle phosphor contained is not particularly limited. However, the amount relative to 100 parts by weight of the ionic liquid having a polymerizable functional group is preferably in a range of 0.001 to 50 parts by weight, more preferably in a range of 0.01 to 20 parts by weight. This is because, when the amount of semiconductor nanoparticle phosphor contained is less than 0.001 parts by weight relative to 100 parts by weight of the ionic liquid having a polymerizable functional group, the emission from the semiconductor nanoparticle phosphor tends to have a very low intensity; on the other hand, when the amount of semiconductor nanoparticle phosphor contained is more than 50 parts by weight relative to 100 parts by weight of the ionic liquid having a polymerizable functional group, uniform dispersion in the ionic liquid having a polymerizable functional group tends to become difficult to achieve.

The method of turning an article (polymer matrix) into particles, the article including a semiconductor nanoparticle phosphor dispersed in a resin including a constitutional unit derived from an ionic liquid having a polymerizable functional group, is not particularly limited. For example, the polymer matrix may be physically pulverized such that the resultant particles have a particle size that is equal to or larger than the particle size d of the semiconductor nanoparticle phosphor and that is equal to or smaller than the minimum thickness L of the wavelength conversion member.

In phosphor-containing particles according to the present disclosure, ions forming the ionic liquid are coordinated to the surface of the semiconductor nanoparticle phosphor to stabilize the nanoparticles, which enables a high emission efficiency. The semiconductor nanoparticle phosphor is dispersed in the resin including a constitutional unit derived from an ionic liquid having a polymerizable functional group, the resin having a low permeability to oxygen and moisture. As a result, agglomeration of the semiconductor nanoparticle phosphor during production of phosphor-containing particles is prevented to maintain high optical characteristics, and degradation of the semiconductor nanoparticle phosphor caused by moisture and oxygen is reduced even after production of the phosphor-containing particles. Thus, when the semiconductor nanoparticle phosphor is excited to emit light, photooxidation is less likely to occur and hence the semiconductor nanoparticle phosphor has high chemical stability.

The phosphor-containing particles according to the present disclosure may have a shape appropriately selected from known shapes such as a spherical shape, a rod shape, and a wire shape. From the viewpoint of ease of control of emission characteristics by controlling the shape, the phosphor-containing particles may have a spherical shape, in particular, a perfect spherical shape.

The particle size of the phosphor-containing particles according to the present disclosure is not particularly limited, but is preferably in a range of 100 nm to 30 μm, more preferably in a range of 1 to 30 μm. This is because, when the particle size of the phosphor-containing particles is less than 100 nm, the surface area/volume ratio of each phosphor-containing particle is increased, so that loss due to scattering of excitation light tends to increase; on the other hand, when the particle size of the phosphor-containing particles is more than 30 μm, it tends to become difficult to disperse the phosphor-containing particles in a light-transmitting medium by the same process as in existing phosphors.

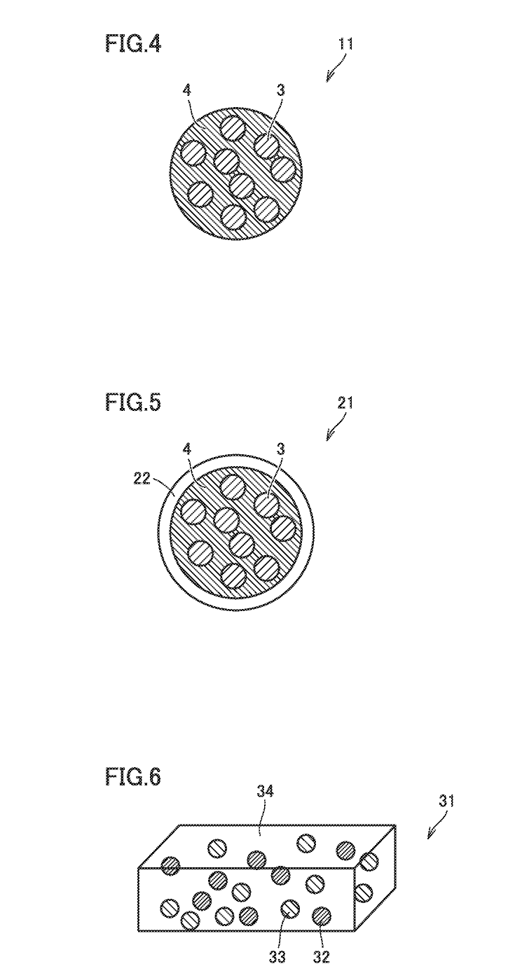

FIG. 4 is a schematic view illustrating a phosphor-containing particle 11 having a particle size in a range of 1 to 30 μm. Incidentally, in FIG. 4, like elements in the phosphor-containing particle 2 according to an embodiment in FIG. 1A are denoted by like reference signs and descriptions thereof will be omitted. As illustrated in the embodiment in FIG. 4, when the phosphor-containing particle 11 has a particle size in a range of 1 to 30 μm, such particles are easily handled. The phosphor-containing particles 11 are thus produced so as to have a size similar to that of currently used phosphors, so that, as with the currently commercially used phosphors, the phosphor-containing particles are dispersed in a light-transmitting medium. Thus, the currently used process without changes is used without causing, for example, clogging of the dispenser or sedimentation, to thereby provide, for example, a wavelength conversion member and a light-emitting device using the phosphor-containing particles. Incidentally, the particle size of the phosphor-containing particle denotes the particle size determined by observation with an optical microscope or a scanning electron microscope (SEM), or the value of the particle size measured with a particle size distribution analyzer.

In the wavelength conversion member according to the present disclosure, the light-transmitting medium 5 in which the phosphor-containing particles are dispersed is not particularly limited. Examples of the light-transmitting medium 5 include epoxy, silicone, (meth)acrylate, silica glass, silica gel, siloxane, sol-gel, hydrogel, agarose, cellulose, epoxy, polyether, polyethylene, polyvinyl, polydiacetylene, polyphenylenevinylene, polystyrene, polypyrrole, polyimide, polyimidazole, polysulfone, polythiophene, polyphosphate, poly(meth)acrylate, polyacrylamide, polypeptides, and polysaccharides. The light-transmitting medium 5 may be provided as a combination of two or more of the foregoing.

The present disclosure also provides a light-emitting device including the above-described wavelength conversion member according to an embodiment and a light source that is disposed as another member in addition to the wavelength conversion member and emits excitation light to the wavelength conversion member. The term “another member” means that the wavelength conversion member and the light source are different members and are not formed as one piece.

In the light-emitting device according to the present disclosure, the light source is not particularly limited and may be selected from, for example, light-emitting diodes (LEDs) and laser diodes (LDs).

FIG. 5 is a schematic view illustrating a phosphor-containing particle 21 according to another embodiment of the present disclosure. Incidentally, in FIG. 5, like elements in the phosphor-containing particle 2 according to an embodiment in FIG. 1A are denoted by like reference signs and descriptions thereof will be omitted. The phosphor-containing particle 21 according to an embodiment in FIG. 5 has the outermost surface including a light-transmitting cover layer 22, which is different from the phosphor-containing particle 2 according to an embodiment in FIG. 1A. The light-transmitting cover layer 22 provided at the outermost surface enables a reduction in the permeability to oxygen and moisture. As a result, degradation of the semiconductor nanoparticle phosphor by photooxidation is significantly reduced or prevented, and the chemical stability of the semiconductor nanoparticle phosphor can be further enhanced.

The material forming the cover layer 22 is not particularly limited as long as it is a light-transmitting material. The material may be selected from light-transmitting inorganic materials such as metal oxides and silica-based materials. Of such materials of the cover layer 22, inorganic materials having a band gap of 3.0 eV or more may be used. Examples of a metal oxide inorganic material that has a band gap of 3.0 eV or more and absorbs ultraviolet rays include SiO₂, ZnO, TiO₂, CeO₂, SnO₂, ZrO₂, Al₂O₃, and ZnO:Mg. Of these, ZnO, TiO₂, Al₂O₃, CeO₂, and SnO₂ have band gaps close to 3.0 eV and hence absorb a wide range of ultraviolet rays (even visible-side ultraviolet rays). On the other hand, SiO₂, ZrO₂, and ZnO:Mg have band gaps much larger than 3.0 eV, and hence absorb only very-short-wavelength ultraviolet rays and transmit visible-side ultraviolet rays. The cover layer 22 formed of an inorganic material having a band gap of 3.0 eV or more and formed at the outermost surface enables significant reduction or prevention of degradation (caused by ultraviolet rays) of the semiconductor nanoparticle phosphor and the resin including a constitutional unit derived from an ionic liquid having a polymerizable functional group, which results in enhancement of the chemical stability. In the present disclosure, the inorganic material may be inorganic crystals.

FIG. 6 is a schematic view illustrating a wavelength conversion member 31 according to another embodiment of the present disclosure. The wavelength conversion member 31 according to an embodiment in FIG. 6 includes phosphor-containing particles 32 in which a red-fluorescence-emitting semiconductor nanoparticle phosphor is dispersed in a resin including a constitutional unit derived from an ionic liquid having a polymerizable functional group, and phosphor-containing particles 33 in which a green-fluorescence-emitting semiconductor nanoparticle phosphor is dispersed in a resin including a constitutional unit derived from an ionic liquid having a polymerizable functional group, which is different from the wavelength conversion member 1 according to an embodiment in FIG. 1B.

As described above, the phosphor-containing particles according to the present disclosure are easily handled; when the phosphor-containing particles are produced so as to have a size similar to that of the currently used phosphors, the phosphor-containing particles are used as with the currently commercially used phosphors by the currently used process without changes. The wavelength conversion member 31 according to an embodiment in FIG. 6 may be subjected to the same process as in the existing phosphors to produce a light-emitting device; in addition, phosphor-containing particles containing a semiconductor nanoparticle phosphor for a different wavelength may be used to produce a light-emitting device that emits light of a desired color. As in the wavelength conversion member 31 according to an embodiment in FIG. 6, in the case of a combination of the phosphor-containing particles 32 in which a red-fluorescence-emitting semiconductor nanoparticle phosphor is dispersed in a resin including a constitutional unit derived from an ionic liquid having a polymerizable functional group, and the phosphor-containing particles 33 in which a green-fluorescence-emitting semiconductor nanoparticle phosphor is dispersed in a resin including a constitutional unit derived from an ionic liquid having a polymerizable functional group, a light-emitting diode (LED) that emits blue light, a laser diode (LD) that emits blue light, or the like may be used as a light source to provide a light-emitting device that emits white light with high color reproduction.

In the wavelength conversion member 31 according to an embodiment in FIG. 6, the mixing ratio of the phosphor-containing particles 33 in which a green-fluorescence-emitting semiconductor nanoparticle phosphor is dispersed in a resin including a constitutional unit derived from an ionic liquid having a polymerizable functional group to the phosphor-containing particles 32 in which a red-fluorescence-emitting semiconductor nanoparticle phosphor is dispersed in a resin including a constitutional unit derived from an ionic liquid having a polymerizable functional group is not particularly limited. This mixing ratio, as a weight ratio of the phosphor-containing particles 33 relative to the weight (defined as 100) of the phosphor-containing particles 32, is preferably in a range of 10 to 1000, more preferably in a range of 20 to 500. This is because, when the weight ratio of the phosphor-containing particles 33 relative to the weight (defined as 100) of the phosphor-containing particles 32 is less than 10, the color of the emitted light tends to considerably deviate from white due to the emission intensity difference between the red light and the green light, and the color of the emitted light deviates toward red; on the other hand, when the weight ratio of the phosphor-containing particles 33 relative to the weight (defined as 100) of the phosphor-containing particles 32 is more than 1000, the color of the emitted light tends to considerably deviate from white due to the emission intensity difference between the red light and the green light, and the color of the emitted light deviates toward green.

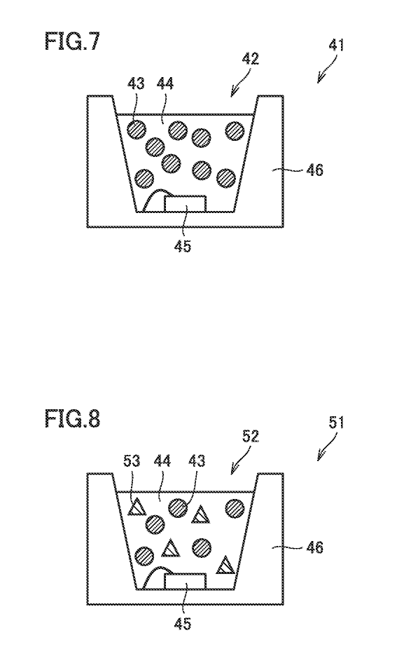

FIG. 7 is a schematic view illustrating a light-emitting device 41 according to an embodiment of the present disclosure. As illustrated in FIG. 7, the present disclosure also provides a light-emitting device (LED package) including a light source 45, and a wavelength converter 42 joined to the light source 45 so as to cover at least a portion of the light source 45, the wavelength converter 42 including phosphor-containing particles 43 dispersed in a light-transmitting medium 44, the phosphor-containing particles 43 including a semiconductor nanoparticle phosphor dispersed in a resin including a constitutional unit derived from an ionic liquid having a polymerizable functional group. The phrase “joined to the light source 45 so as to cover” means that the wavelength converter 42 is formed so as to be fixed to and seal at least a portion of the light source 45 (for example, as in the embodiment in FIG. 7, the upper surface and side surface of the light source 45). The light-emitting device illustrated in FIG. 7 has, as one of features, the following feature as in the above-described light-emitting device including a wavelength conversion member and a light source that is disposed as another member in addition to the wavelength conversion member: the phosphor-containing particles have a particle size that is equal to or larger than the particle size of the semiconductor nanoparticle phosphor and that is equal to or smaller than the minimum thickness of the wavelength converter. The “minimum thickness” of each of such wavelength converters having different shapes denotes, as with the above-described minimum thickness of the wavelength conversion member, in a portion having the minimum linear distance in the wavelength converter, this linear distance. Also in the light-emitting device illustrated in FIG. 7, the phosphor-containing particles 43 may have a particle size that is equal to or larger than twice the particle size of the semiconductor nanoparticle phosphor and that is equal to or smaller than ½ of the minimum thickness of the wavelength converter 42.

As described above, the phosphor-containing particles according to the present disclosure are easily handled. When the phosphor-containing particles are produced so as to have a size similar to that of the currently used phosphors, the phosphor-containing particles are used as with the currently commercially used phosphors by the currently used process without changes. In the light-emitting device 41 illustrated in FIG. 7, elements including the light source 45, the light-transmitting medium 44, a frame 46, and a lead are appropriately selected from known elements without particular limitation.

FIG. 7 illustrates a case in which the phosphor-containing particles 43 are the same as the phosphor-containing particle 2 illustrated in FIG. 1A. Alternatively, as in the embodiment illustrated in FIG. 5, the phosphor-containing particle having a cover layer may be used. As in the embodiment illustrated in FIG. 6, it is obviously possible to use the phosphor-containing particles in which a red-fluorescence-emitting semiconductor nanoparticle phosphor is dispersed in a resin including a constitutional unit derived from an ionic liquid having a polymerizable functional group, and the phosphor-containing particles in which a green-fluorescence-emitting semiconductor nanoparticle phosphor is dispersed in a resin including a constitutional unit derived from an ionic liquid having a polymerizable functional group.

FIG. 8 is a schematic view illustrating a light-emitting device 51 according to another embodiment of the present disclosure. In FIG. 8, like elements in the light-emitting device 41 according to an embodiment in FIG. 7 are denoted by like reference signs and descriptions thereof will be omitted. In a wavelength converter 52 in the light-emitting device 51 according to an embodiment in FIG. 8, in addition to the phosphor-containing particles 43 according to an embodiment, a phosphor (existing phosphor) 53 other than semiconductor nanoparticle phosphors is dispersed in the medium 44, which is different from the light-emitting device 41 according to an embodiment in FIG. 7. In this way, in the present disclosure, phosphor-containing particles according to an embodiment may be combined with an existing phosphor to provide a light-emitting device that emits light having a desired color.

The existing phosphor 53 is not particularly limited and examples thereof include inorganic phosphors including rare-earth-activated oxynitride phosphors such as α-SIALON phosphor, β-SIALON phosphor, JEM blue phosphor (LaAl(Si_{6-z}Al_{z})N_{10-z}O_{z}), and γ-AlON phosphor, oxide phosphors such as YAG:Ce-based phosphor, and nitride phosphors such as CASN phosphor (CaAlSiN₃); and organic pigments including azo pigments such as soluble azo pigment, insoluble azo pigment, benzimidazolone pigment, β-naphthol pigment, naphthol AS pigment, and condensed azo pigment, and polycyclic pigments such as phthalocyanine pigment, quinacridone pigment, perylene pigment, isoindolinone pigment, isoindoline pigment, dioxazine pigment, thioindigo pigment, anthraquinone pigment, quinophthalone pigment, metal complex pigment, and diketopyrrolopyrrole pigment, and dye lake pigments. In particular, in order to achieve high chemical stability and high color rendering properties, the existing phosphor 53 may be selected from inorganic phosphors.

In the light-emitting device 51 according to an embodiment in FIG. 8, the mixing ratio of the existing phosphor to the phosphor-containing particles is also not particularly limited and varies depending on, for example, the type of semiconductor nanoparticle phosphor and existing phosphor used. When the semiconductor nanoparticle phosphor contained in the phosphor-containing particles is CdSe and the existing phosphor is β-SIALON phosphor, the weight ratio of the existing phosphor relative to the weight (defined as 100) of the phosphor-containing particles is preferably in a range of 10 to 1000, more preferably in a range of 20 to 500.

FIG. 8 illustrates a case in which the phosphor-containing particles 43 are the same as the phosphor-containing particle 2 illustrated in FIG. 1A. Alternatively, as in the embodiment illustrated in FIG. 5, phosphor-containing particles having a cover layer may be used. As in the embodiment illustrated in FIG. 6, it is obviously possible to use the phosphor-containing particles in which a red-fluorescence-emitting semiconductor nanoparticle phosphor is dispersed in a resin including a constitutional unit derived from an ionic liquid having a polymerizable functional group, and the phosphor-containing particles in which a green-fluorescence-emitting semiconductor nanoparticle phosphor is dispersed in a resin including a constitutional unit derived from an ionic liquid having a polymerizable functional group.

The present disclosure contains subject matter related to that disclosed in Japanese Priority Patent Application JP 2017-002474 filed in the Japan Patent Office on Jan. 11, 2017, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A wavelength conversion member comprising:
a light-transmitting medium; and
phosphor-containing particles dispersed in the light-transmitting medium and including
a resin including a constitutional unit derived from an ionic liquid having a polymerizable functional group and
a semiconductor nanoparticle phosphor dispersed in the resin,
wherein the phosphor-containing particles have a particle size that is equal to or larger than a particle size of the semiconductor nanoparticle phosphor and that is equal to or smaller than a minimum thickness of the wavelength conversion member.

2. A light-emitting device comprising:
the wavelength conversion member according to claim 1; and
a light source configured to emit excitation light to the wavelength conversion member, and disposed as another member in addition to the wavelength conversion member.

3. The light-emitting device according to claim 2, wherein the particle size of the phosphor-containing particles is equal to or larger than twice the particle size of the semiconductor nanoparticle phosphor, and is equal to or smaller than ½ of the minimum thickness of the wavelength conversion member.

4. The light-emitting device according to claim 2, wherein the particle size of the phosphor-containing particles is in a range of 1 to 30 μm.

5. The light-emitting device according to claim 2, wherein the phosphor-containing particles have an outermost surface including a light-transmitting cover layer.

6. The light-emitting device according to claim 5, wherein the cover layer is formed of an inorganic material having a band gap of 3.0 eV or more.

7. The light-emitting device according to claim 2, wherein the polymerizable functional group is a (meth)acrylate group.

8. The light-emitting device according to claim 2, wherein the semiconductor nanoparticle phosphor includes a semiconductor nanoparticle phosphor configured to emit red fluorescence and a semiconductor nanoparticle phosphor configured to emit green fluorescence.

9. The light-emitting device according to claim 2, wherein, in the medium, a phosphor other than the semiconductor nanoparticle phosphor is further dispersed.

10. A light-emitting device comprising:
a light source; and
a wavelength converter joined to the light source so as to cover at least a portion of the light source and including
a light-transmitting medium, and
phosphor-containing particles dispersed in the light-transmitting medium and including
a resin including a constitutional unit derived from an ionic liquid having a polymerizable functional group, and
a semiconductor nanoparticle phosphor dispersed in the resin,
wherein the phosphor-containing particles have a particle size that is equal to or larger than a particle size of the semiconductor nanoparticle phosphor and that is equal to or smaller than a minimum thickness of the wavelength converter.

11. The light-emitting device according to claim 10, wherein the particle size of the phosphor-containing particles is equal to or larger than twice the particle size of the semiconductor nanoparticle phosphor, and is equal to or smaller than ½ of the minimum thickness of the wavelength converter.

12. The light-emitting device according to claim 10, wherein the particle size of the phosphor-containing particles is in a range of 1 to 30 μm.

13. The light-emitting device according to claim 10, wherein the phosphor-containing particles have an outermost surface including a light-transmitting cover layer.

14. The light-emitting device according to claim 13, wherein the cover layer is formed of an inorganic material having a band gap of 3.0 eV or more.

15. The light-emitting device according to claim 10, wherein the polymerizable functional group is a (meth)acrylate group.

16. The light-emitting device according to claim 10, wherein the semiconductor nanoparticle phosphor includes a semiconductor nanoparticle phosphor configured to emit red fluorescence and a semiconductor nanoparticle phosphor configured to emit green fluorescence.

17. The light-emitting device according to claim 10, wherein, in the medium, a phosphor other than the semiconductor nanoparticle phosphor is further dispersed.
